(19) United States
(12) Patent Application Publication
(10) Pub. No.: US 2025/0069908 A1
(43) Pub. Date: Feb. 27, 2025

(54) SUBSTRATE PROCESSING APPARATUS

(71) Applicant: SEMES CO., LTD., Cheonan-si (KR)

(72) Inventors: Youngjoon Han, Cheonan-si (KR); Kyuhwan Chang, Cheonan-si (KR); Juha Woo, Anseong-si (KR)

(21) Appl. No.: 18/779,123

(22) Filed: Jul. 22, 2024

(30) Foreign Application Priority Data
Aug. 23, 2023 (KR) 10-2023-0110758

(51) Int. Cl. H01L 21/67; B05B 1/26

(52) U.S. Cl. CPC H01L 21/6708; B05B 1/26

(57) ABSTRACT

A substrate processing apparatus includes a support unit configured to support a substrate and be rotatable, a chemical liquid supply nozzle configured to supply a chemical liquid to a chemical liquid supply area of the substrate, and a charging unit disposed adjacent to the substrate. The charging unit is disposed adjacent to the chemical liquid supply nozzle, and is charged with charges opposite to charges of the chemical liquid.

### CROSS-REFERENCE TO RELATED APPLICATION

This application is based on and claims priority under 35 U.S.C. § 119 to Korean Patent Application No. 10-2023-0110758, filed on Aug. 23, 2023, in the Korean Intellectual Property Office, the disclosure of which is incorporated by reference herein in its entirety.

### BACKGROUND

### 1. Field

The disclosure relates to a substrate processing apparatus.

### 2. Description of the Related Art

When manufacturing a semiconductor device or display device, various processes such as photography, etching, ashing, ion implantation, and thin film deposition are performed. Etching is a process of removing a film formed on a substrate, and a cleaning process is a process of removing contaminants remaining on the surface of a substrate. The etching/cleaning process is classified into wet and dry methods according to a process progress, and the wet method is classified into a batch type and a spin type. In the spin-type method, a substrate is fixed to a support module capable of processing a single substrate, and then a chemical is supplied to the substrate through a nozzle while rotating the substrate such that the chemical is spread across the entire surface of the substrate by the centrifugal force.

### SUMMARY

The disclosure provides a substrate processing apparatus capable of preventing contamination of a substrate by capturing liquid droplets scattering on the substrate.

In addition, the problems to be solved by the disclosure are not limited to the aforementioned problems, and other problems may be clearly understood by those skilled in the art from the following description.

Additional aspects will be set forth in part in the description which follows and, in part, will be apparent from the description, or may be learned by practice of the presented embodiments of the disclosure.

According to an embodiment of the disclosure, a substrate processing apparatus includes a support unit configured to support a substrate and be rotatable, a chemical liquid supply nozzle configured to supply a chemical liquid to a chemical liquid supply area of the substrate, a collection cup configured to provide a space for collecting the chemical liquid, and a charging unit disposed adjacent to the substrate. The charging unit is configured to capture droplets of the chemical liquid that collide with the substrate and scatter, and is charged with charges opposite to charges of the chemical liquid.

The charging unit is arranged to be spaced apart from the collection cup in a horizontal direction perpendicular to the support unit. When the chemical liquid has positive charges, the charging unit is charged with negative charges, and, when the chemical liquid has negative charges, the charging unit is charged with positive charges.

The charging unit includes a first body extending in a vertical direction perpendicular to the substrate, a second body connected to the first body and extending in an inclined direction with respect to the first body, and a protrusion protruding from the second body toward an upper surface of the substrate.

The first body is arranged to be spaced apart from the support unit, and a length of the second body is less than a length of the first body.

The charging unit is arranged not to vertically overlap the substrate.

The charging unit includes a first charging unit and a second charging unit arranged to be spaced apart from the first charging unit in a horizontal direction perpendicular to the support unit. The first charging unit is arranged to be symmetrical with the second charging unit about the substrate. The first charging unit includes a first body extending in a vertical direction perpendicular to the substrate, a second body connected to the first body and extending in an inclined direction with respect to the first body, and a first protrusion protruding from the second body toward an upper surface of the substrate. The second charging unit includes a third body extending in the vertical direction perpendicular to the substrate, a fourth body connected to the third body and extending in an inclined direction with respect to the third body, and a second protrusion protruding from the fourth body toward the upper surface of the substrate.

At least one charging unit among the first charging unit and the second charging unit is charged with charges opposite to charges of the chemical liquid.

The collection cup includes a conductive member, and is charged with charges opposite to charges of the chemical liquid.

The charging unit is in contact with the collection cup, and includes a plurality of ring members arranged to be spaced apart from the substrate in a vertical direction perpendicular to the substrate.

The charging unit includes a first ring member and a second ring member, and a center of each of the first ring member and the second ring member coincides with a center of the substrate.

A diameter of the first ring member is greater than a diameter of the substrate, and a diameter of the second ring member is greater than the diameter of the first ring member.

The charging unit has a ring shape, and a width of the charging unit decreases in a direction away from the substrate.

The charging unit includes a plurality of holes arranged in an outer circumferential surface of the charging unit, and the plurality of holes are arranged in the outer circumferential surface in a matrix form.

According to another embodiment of the disclosure, a substrate processing apparatus includes a housing configured to provide a processing space, a support unit having a chuck for supporting a lower surface of a substrate in the processing space and a chuck pin formed to contact a lateral surface of the substrate, the support unit extending in a vertical direction perpendicular to a bottom surface of the housing, a chemical liquid supply nozzle configured to supply a chemical liquid to a chemical liquid supply area of the substrate, a charging unit disposed adjacent to the substrate, a collection cup disposed within the housing and configured to collect the chemical liquid, and a controller configured to control the chemical liquid supply nozzle, the charging unit, and the support unit. The charging unit is in contact with the collection cup, is disposed to be spaced apart from the substrate in the vertical direction, and has a ring shape.

The chemical liquid supply nozzle moves in a horizontal direction perpendicular to the vertical direction on the substrate, and the charging unit is grounded when the chemical liquid supply nozzle is disposed on a central axis of the substrate.

The charging unit includes a first ring member and a second ring member spaced apart from each other, a diameter of the first ring member and a diameter of the second ring member are greater than a diameter of the substrate, and the diameter of the first ring member is less than the diameter of the second ring member.

A width of the charging unit decreases in a direction away from the substrate in the vertical direction, the charging unit includes a plurality of holes, and the plurality of holes are arranged in an outer circumferential surface of the charging unit in a matrix form.

According to another embodiment of the disclosure, a substrate processing apparatus includes a housing configured to provide a processing space, a support unit having a chuck for supporting a lower surface of a substrate in the processing space and a chuck pin formed to contact a lateral surface of the substrate, the support unit extending in a vertical direction perpendicular to a bottom surface of the housing, a chemical liquid supply nozzle configured to supply a chemical liquid to a chemical liquid supply area of the substrate, a charging unit disposed adjacent to the substrate, a collection cup disposed within the housing and configured to collect the chemical liquid, and a controller configured to control the chemical liquid supply nozzle, the charging unit, and the support unit. The charging unit is disposed to be spaced apart from the substrate in the vertical direction, and has a ring shape. The charging unit is charged with charges opposite to the chemical liquid when the chemical liquid supply nozzle is disposed on a lateral surface of the substrate, and is grounded when the chemical liquid supply nozzle is disposed on a central axis of the substrate.

The charging unit and the collection cup are charged with charges of the same type.

The charging unit includes a first ring member and a second ring member, a center of each of the first ring member and the second ring member is greater than a center of the substrate, a diameter of the first ring member is greater than a diameter of the substrate, and a diameter of the second ring member is greater than the diameter of the first ring member.

### BRIEF DESCRIPTION OF THE DRAWINGS

The above and other aspects, features, and advantages of certain embodiments of the inventive concept will be more apparent from the following description taken in conjunction with the accompanying drawings, in which:

FIG. 1 is a schematic plan view of a substrate processing system according to an embodiment of the disclosure;

FIG. 2 is a schematic diagram of an embodiment of a substrate processing apparatus of FIG. 1;

FIGS. 3 through 5 are diagrams for explaining a charging unit of a substrate processing apparatus according to an embodiment of the disclosure;

FIGS. 6 through 8 are diagrams for explaining a first charging unit and a second charging unit of a substrate processing apparatus according to embodiments of the disclosure;

FIG. 9 is a schematic diagram of the substrate processing apparatus of FIG. 2 according to an embodiment;

FIG. 10 is a schematic diagram of the substrate processing apparatus of FIG. 2 according to an embodiment;

FIG. 11 is a view for explaining a charging unit of FIG. 10;

FIG. 12 is a schematic diagram of the substrate processing apparatus of FIG. 2 according to an embodiment;

FIG. 13 is a view for explaining a charging unit of FIG. 12;

FIG. 14 is a schematic diagram of the substrate processing apparatus of FIG. 2 according to an embodiment;

FIG. 15 is a view for explaining a charging unit of FIG. 14; and

FIG. 16 is a schematic diagram of the substrate processing apparatus of FIG. 2 according to an embodiment.

### DETAILED DESCRIPTION

Throughout the disclosure, the expression “at least one of a, b or c” indicates only a, only b, only c, both a and b, both a and c, both b and c, all of a, b, and c, or variations thereof.

The disclosure will now be described more fully with reference to the accompanying drawings, in which exemplary embodiments of the disclosure are shown. However, the disclosure does not have to be configured as limited to the embodiments described below, and may be embodied in various other forms. The following embodiments are not provided to fully complete the disclosure, but rather are provided to fully convey the scope of the disclosure to those skilled in the art.

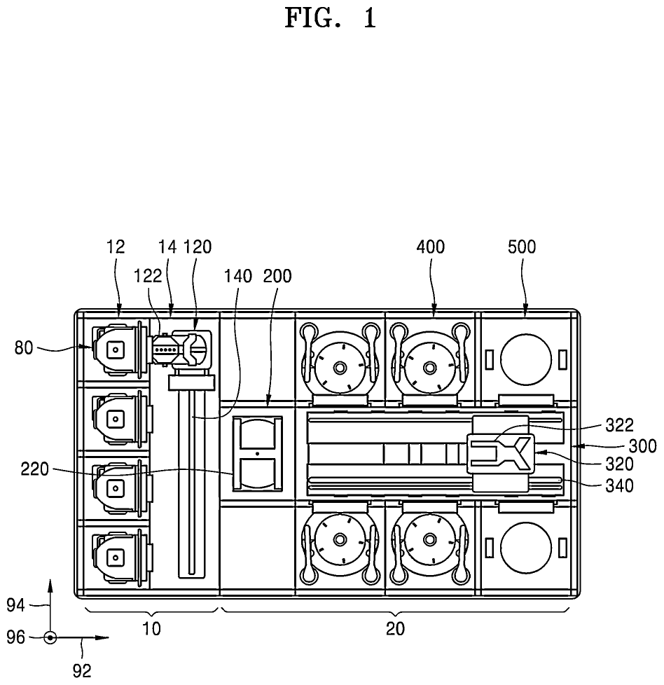

FIG. 1 is a schematic plan view of a substrate processing system according to an embodiment of the disclosure.

Referring to FIG. 1, the substrate processing system includes an index module 10 and a processing module 20. According to an embodiment, the index module 10 and the processing module 20 are arranged in one direction. Hereinafter, a direction in which the index module 10 and the processing module 20 are arranged is referred to as a first direction 92, a direction perpendicular to the first direction 92 when viewed from the top is referred to as a second direction 94, and a direction perpendicular to both the first direction 92 and the second direction 94 is referred to as a third direction 96.

The index module 10 transfers a substrate W from a container 80 in which the substrate W is accommodated to the processing module 20, and transfers the substrate W that has been processed by the processing module 20 back to the container 80. A lengthwise direction of the index module 10 is provided in the second direction 94. The index module 10 has a load port 12 and an index frame 14. The load port 12 is located on a side of the index frame 14 that is opposite to the processing module 20. The container 80 containing substrates W is placed in the load port 12. The load port 12 may be provided in plurality, and a plurality of load ports 12 may be arranged in the second direction 94.

The container 80 may be an airtight container such as a front open unified pod (FOUP). The container 80 may be placed in the load port 12 by a transfer unit (not shown), such as an overhead transfer, an overhead conveyor, or an automatic guided vehicle, or an operator.

An index robot 120 is provided on the index frame 14. A guide rail 140 in which a lengthwise direction is the second direction 94 may be provided within the index frame 14, and the index robot 120 may be provided to be movable on the guide rail 140. The index robot 120 may include a hand 122 on which the substrate W is placed, and the hand 122 may be provided to be movable forward and backward, rotatable about the third direction 96, and movable in the third direction 96. A plurality of hands 122 may be provided apart from each other in a vertical direction, and the hands 122 may move forward and backward independently of each other.

The processing module 20 includes a buffer unit 200, a transfer apparatus 300, a substrate processing apparatus 400, and a substrate processing apparatus 500.

The buffer unit 200 provides a space where a substrate W carried into the processing module 20 and a substrate W carried out of the processing module 20 temporarily stay. The substrate processing apparatus 400 performs a liquid treatment process of supplying liquid onto the substrate W and process the substrate W with the liquid. The substrate processing apparatus 500 performs a drying process of removing liquid remaining on the substrate W. The transfer apparatus 300 transfers the substrate W between the buffer unit 200, the substrate processing apparatus 400, and the substrate processing apparatus 500.

A lengthwise direction of the transfer apparatus 300 may be provided as the first direction 92. The buffer unit 200 may be disposed between the index module 10 and the transfer apparatus 300. The substrate processing apparatus 400 and the substrate processing apparatus 500 may be disposed on lateral sides of the transfer apparatus 300. The substrate processing apparatus 400 and the transfer apparatus 300 may be arranged in the second direction 94. The substrate processing apparatus 500 and the transfer apparatus 300 may be arranged in the second direction 94. The buffer unit 200 may be located on one end of the transfer apparatus 300.

According to one example, substrate processing apparatuses 400 may be arranged on both sides of the transfer apparatus 300, substrate processing apparatuses 500 may be arranged on both sides of the transfer apparatus 300, and the substrate processing apparatuses 400 may be closer to the buffer unit 200 than the substrate processing apparatuses 500 are. On one side of the transfer apparatus 300, the substrate processing apparatuses 400 may be provided in an A×B (where A and B are natural numbers equal to or greater than 1) configuration in each of the first direction 92 and the third direction 96. On one side of the transfer apparatus 300, the substrate processing apparatuses 500 may be provided in an C×D (where C and D are natural numbers equal to or greater than 1) configuration in each of the first direction 92 and the third direction 96. Unlike the above, only the substrate processing apparatuses 400 may be provided on one side of the transfer apparatus 300, and only the substrate processing apparatuses 500 may be provided on the other side thereof.

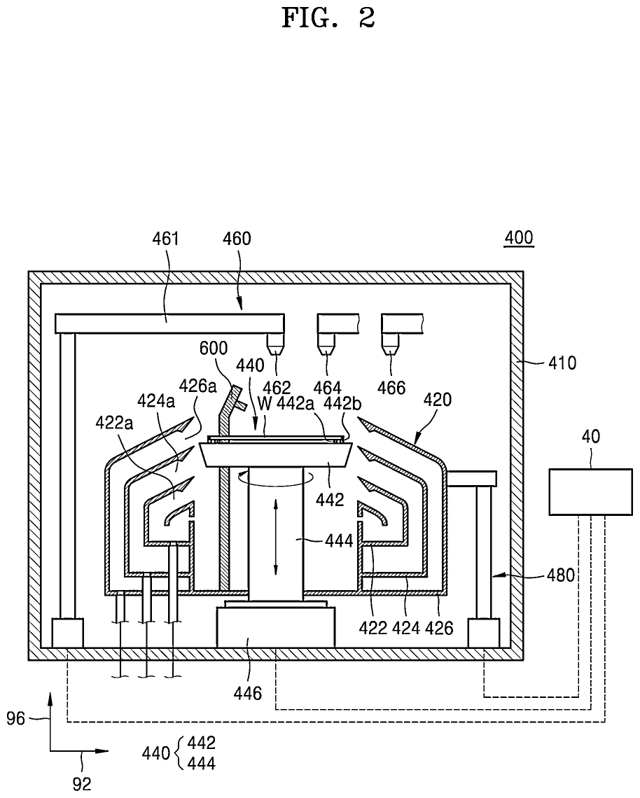

FIG. 2 is a schematic diagram of an embodiment of the substrate processing apparatus 400 of FIG. 1.

Referring to FIG. 2, the substrate processing apparatus 400 includes a housing 410, a collection cup 420, a support unit 440, a liquid supply unit 460, a lifting unit 480, a controller 40, and a charging unit 600. The controller 40 controls operations of the liquid supply unit 460, the support unit 440, and the lifting unit 480. The housing 410 is provided in a generally rectangular parallelepiped shape. The collection cup 420, the support unit 440, and the liquid supply unit 460 are disposed within the housing 410. According to embodiments, the controller 40 may control an operation of the charging unit 600.

The collection cup 420 has a processing space with an open top, and the substrate W undergoes liquid treatment within the processing space. The support unit 440 supports the substrate W within the processing space. The liquid supply unit 460 supplies liquid onto the substrate W supported by the support unit 440. The type of liquid may be provided in plurality, and a plurality of types of liquid may be sequentially supplied onto the substrate W. The lifting unit 480 adjusts a relative height between the collection cup 420 and the support unit 440.

According to an example, the collection cup 420 has a plurality of collection bins 422, 424, and 426. Each of the collection bins 422, 424, and 426 has a collection space for collecting the liquid used for substrate processing. Each of the recovery bins 422, 424, and 426 is provided in a ring shape surrounding the support unit 440. During the liquid treatment, a pretreatment liquid scattered due to a rotation of the substrate W flows into the collection space through respective inlets 422a, 424a, and 426a of the collection bins 422, 424, and 426. According to an example, the collection cup 420 has a first collection bin 422, a second collection bin 424, and a third collection bin 426. The first collection bin 422 is arranged to surround the support unit 440, the second collection bin 424 is arranged to surround the first collection bin 422, and the third collection bin 426 is arranged to surround the second collection bin 426. A second inlet 424a, via which liquid flows into the second collection bin 424, may be located above a first inlet 422a, via which liquid flows into the first collection bin 422, and a third inlet 426a, via which liquid flows into the third collection bin 426, may be located above the second inlet 424a.

The support unit 440 has a support plate 442 and a drive shaft 444. An upper surface of the support plate 442 may be provided in a generally circular shape, and may have a larger diameter than the substrate W. A support pin 442a is provided at a center of the support plate 442 to support a rear surface of the substrate W, and an upper end of the support pin 442a is provided to protrude from the support plate 442 such that the substrate W is spaced a certain distance away from the support plate 442. A chuck pin 442b is provided at an edge of the support plate 442.

The chuck pin 442b is provided to protrude upward from the support plate 442, and supports a lateral portion of the substrate W such that the substrate W does not separate from the support unit 440 when the substrate W is rotated. The drive shaft 444 is driven by a driver 446, is connected to a center of a lower surface of the substrate W, and rotates the support plate 442 about its central axis.

According to an example, the liquid supply unit 460 has a chemical liquid supply nozzle 462, a first nozzle 464, and a second nozzle 466. The chemical liquid supply nozzle 462 supplies a chemical liquid onto the substrate W. The chemical liquid may be a liquid that removes a film or foreign substances remaining on the substrate W. The first nozzle 464 supplies a first liquid onto the substrate W. The first liquid may be a liquid that dissolves well in a second liquid. For example, the first liquid may be a liquid that dissolves better in the second liquid than in the chemical liquid. The first liquid may be a liquid that neutralizes the chemical liquid supplied to the substrate W. The first liquid may be a liquid that neutralizes the chemical liquid and simultaneously dissolves better in the second liquid than in the chemical liquid.

According to an example, the first liquid may be water. The second nozzle 466 supplies the second liquid onto the substrate W. The second liquid may be a liquid that dissolves well in a supercritical fluid used in the substrate processing apparatus 500. For example, the second liquid may be a liquid that dissolves better in the supercritical fluid used in the substrate processing apparatus 500 than in the first liquid. According to an example, a third liquid may be an organic solvent. The organic solvent may be isopropyl alcohol (IPA). According to an example, the supercritical fluid may be carbon dioxide.

The chemical liquid supply nozzle 462, the first nozzle 464, and the second nozzle 466 may be supported by different arms 461, and these arms 461 may be moved independently. Selectively the chemical liquid supply nozzle 462, the first nozzle 464, and the second nozzle 466 may be mounted on the same arm 461, and may be moved simultaneously. The lifting unit 480 moves the collection bin 420 in a vertical direction. A relative height between the collection bin 420 and the substrate W changes due to the vertical movement of the collection bin 420. Accordingly, the collection bins 422, 424, and 426 for collecting a pretreatment liquid are changed according to the type of liquid supplied to the substrate W, and thus may separately collect liquids. Unlike the above-description, the collection bin 420 may be fixedly installed, and the lifting unit 480 may move the support unit 440 in the vertical direction.

The charging unit 600 may be disposed adjacent to the substrate W. The charging unit 600 may be arranged to be spaced apart from the substrate W and the support unit 440 in the first direction 92. The charging unit 600 may be charged with negative or positive charge. A portion of the charging unit 600 may protrude toward the substrate W. The charging unit 600 may capture droplets scattering from the substrate W. According to embodiments, the charging unit 600 may capture droplets scattering from the center of the substrate W toward the outside of the substrate W. Accordingly, the charging unit 600 may prevent the chemical liquid from scattering from the substrate W and flowing into the center of the substrate W. The charging unit 600 may be arranged so as not to vertically overlap the substrate W in the third direction 96.

The substrate processing apparatus 400 may not include a cover member (not shown). The cover member may include a structure for preventing a chemical liquid from scattering within a substrate. The cover member may be disposed over an inside portion of the substrate W to face the upper surface of the substrate W, and may have a ring shape.

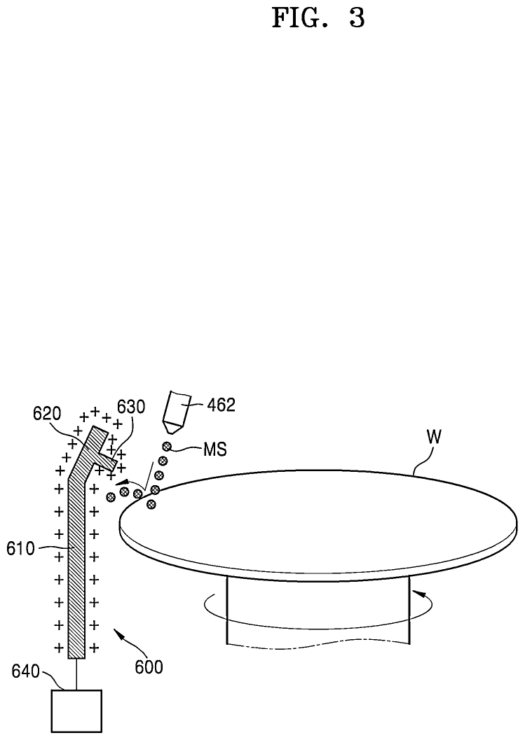

The charging unit 600 will now be described in detail with reference to FIGS. 3 through 8.

FIGS. 3 through 5 are diagrams for explaining the charging unit 600 of the substrate processing apparatus 400 according to an embodiment of the disclosure.

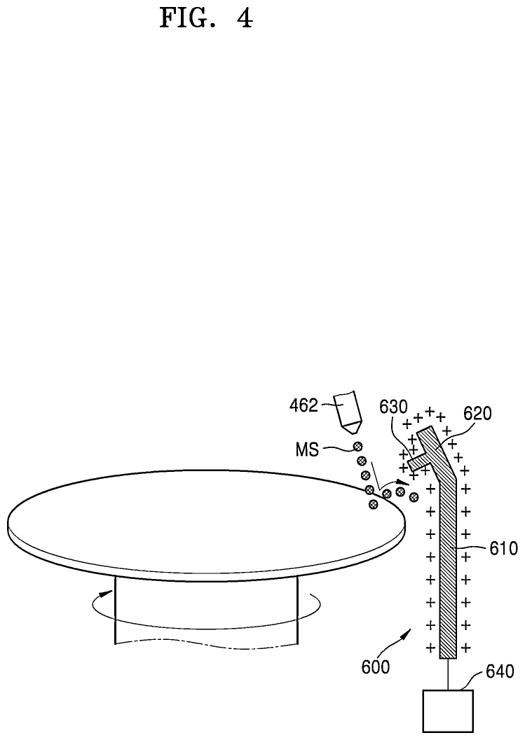

Referring to FIGS. 3 and 4, the charging unit 600 may include a first body 610, a second body 620, and a protrusion 630. Each of the first body 610, the second body 620, and the protrusion 630 may have a rectangular parallelepiped or cylindrical shape. The charging unit 600 may be connected to a power source 640. The power source 640 may charge the charging unit 600.

The first body 610 may extend in a vertical direction perpendicular to the substrate W (e.g., in the third direction 96 in FIG. 2). The second body 620 may be connected to the first body 610 and may extend in an inclined direction with respect to the first body 610. According to embodiments, the second body 620 may extend from an end of the first body 610 in a direction inclined toward the substrate W. The protrusion 630 may protrude from the second body 620 toward the upper surface of the substrate W. The direction in which the protrusion 630 extends may be perpendicular to the direction in which the second body extends. A length of the first body 610 may be less than that of the second body 620. The charging unit 600 may be the collection bin 420 that collects the chemical liquid of FIG. 2.

The charging unit 600 may be arranged to be spaced apart from the substrate W and the support unit 440 of FIG. 2 in a horizontal direction (e.g., in the third direction 92 of FIG. 2). The horizontal direction may be perpendicular to an extension direction of the drive shaft 444 of the support unit 440. According to embodiments, the charging unit 600 may be disposed adjacent to a lateral surface of the substrate W. When the chemical liquid supply nozzle 462 supplies a chemical liquid MS to an edge area of the upper surface of the substrate W, the charging unit 600 may be charged with a charge opposite to a charge of the chemical liquid MS. According to embodiments, when the chemical liquid MS discharged from the chemical liquid supply nozzle 462 has a negative charge, the charging unit 600 may be charged with a positive charge. Unlike shown in FIGS. 3 and 4, when the chemical liquid MS discharged from the chemical liquid supply nozzle 462 has a positive charge, the charging unit 600 may be charged with a negative charge.

The charging unit 600 may be arranged on the left or right side in a horizontal direction with respect to the substrate W and the support unit. The charging unit 600 may move along an outer lateral surface of the substrate W. According to embodiments, the charging unit 600 may move from the left side to the right side in the horizontal direction with respect to the substrate W and the support unit. However, the disclosure is not limited thereto, and the charging unit 600 may be fixed at an adjacent location with respect to the substrate W and the support unit.

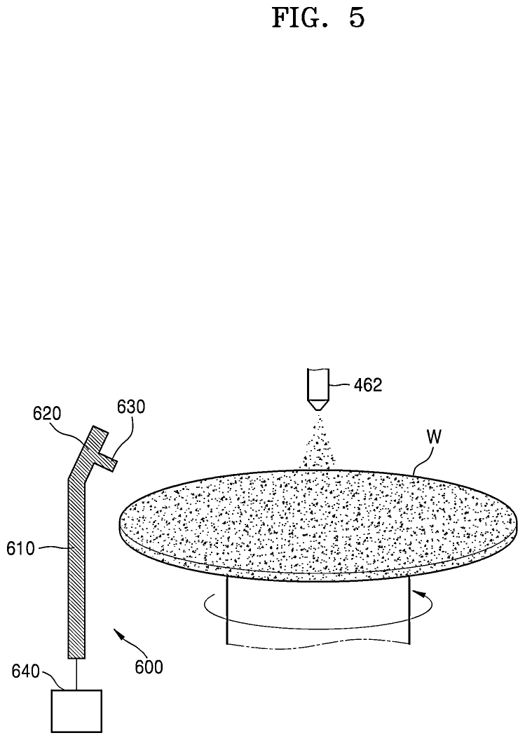

Referring to FIG. 5, when the chemical liquid supply nozzle 462 is disposed at the center or central axis of the substrate W, the charging unit 600 may be grounded or discharged. At this time, the charging unit 640 may be in a neutral state. According to embodiments, when a horizontal separation distance between the chemical liquid supply nozzle 462 and the charging unit 600 exceeds a preset threshold, the charging unit 600 may be grounded or discharged.

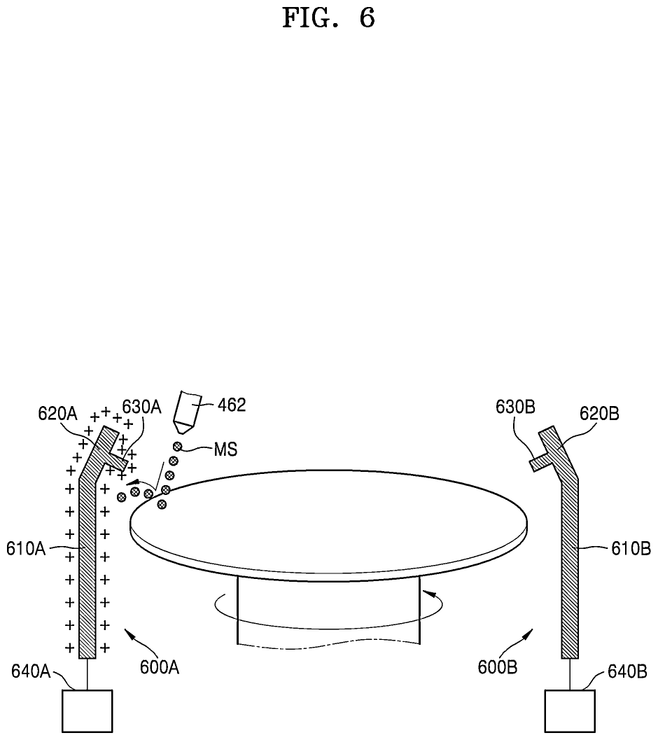

FIGS. 6 through 8 are diagrams for explaining a first charging unit and a second charging unit of a substrate processing apparatus according to embodiments of the disclosure.

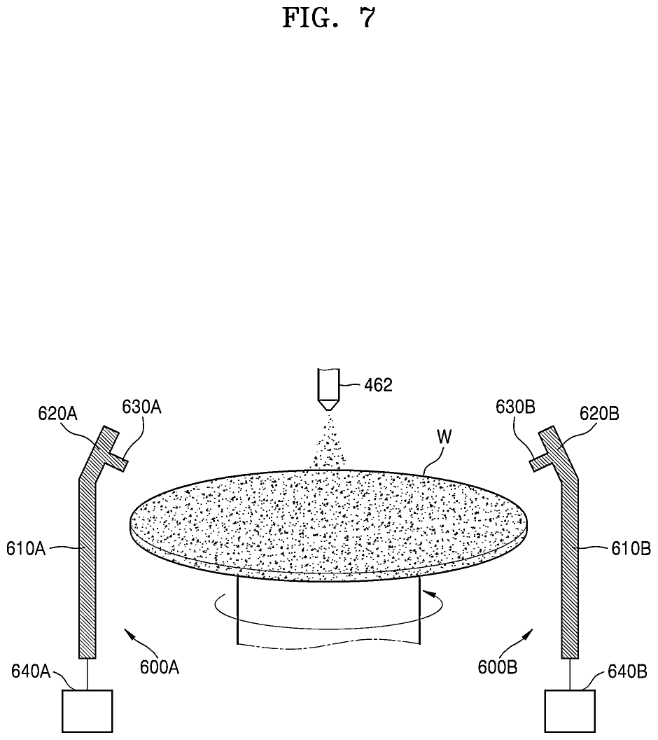

Referring to FIGS. 6 and 7, a charging unit may include a first charging unit 600A and a second charging unit 600B. The first charging unit 600A may include a 1st-1 body 610A, a 1st-2 body 620A, and a first protrusion 630A, and the second charging unit 600B may include a 2nd-1 body 610B, a 2nd-2 body 620B, and a second protrusion 630B. The first charging unit 600A may be charged by being connected to the first power source 640A, and the second charging unit 600B may be charged by being connected to the second power source 640B.

The first charging unit 600A and the second charging unit 600B may be arranged to be spaced apart from each other in the horizontal direction (e.g., in the third direction 92 of FIG. 2). The substrate W and the support unit 440 of FIG. 2 may be arranged between the first charging unit 600A and the second charging unit 600B. According to embodiments, the first charging unit 600A may be disposed on the left side with respect to the substrate W. The second charging unit 600B may be disposed on the right side with respect to the substrate W.

According to embodiments, when the chemical liquid supply nozzle 462 supplies the chemical liquid MS to a left edge area of the substrate W, the first charging unit 600A adjacent to a supply area of the chemical liquid MS may be charged with a charge opposite to the charge of the chemical liquid MS. When the chemical liquid supply nozzle 462 supplies the chemical liquid MS to the left edge area of the upper surface of the substrate W, the second charging unit 600B may be grounded or discharged and thus may be in a neutral state. According to embodiments, when the chemical liquid supply nozzle 462 supplies the chemical liquid MS to a right edge area of the substrate W, the second charging unit 600B adjacent to the supply area of the chemical liquid MS may be charged with a charge opposite to the charge of the chemical liquid MS. When the chemical liquid supply nozzle 462 supplies the chemical liquid MS to the right edge area of the upper surface of the substrate W, the first charging unit 600A may be grounded or discharged and thus may be in a neutral state.

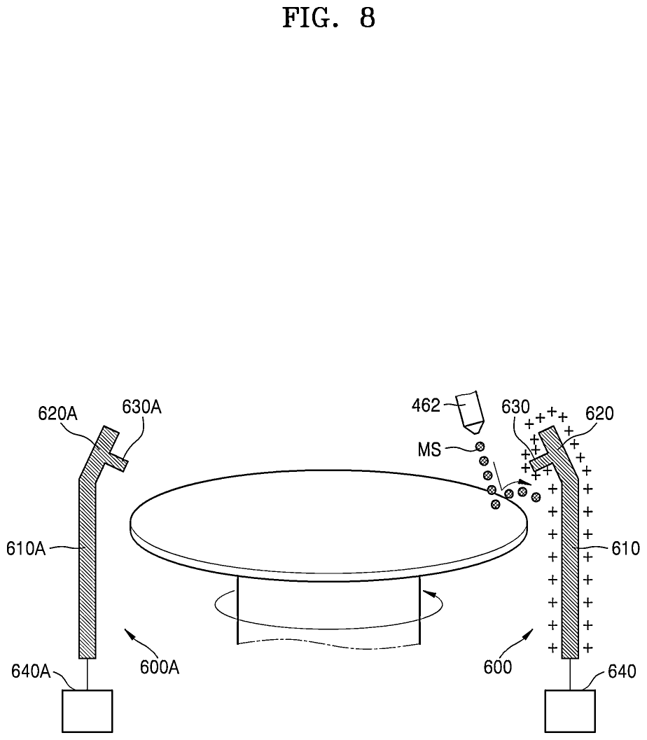

Referring to FIG. 8, when the chemical liquid supply nozzle 462 is disposed at the center of the substrate W, the first charging unit 600A and the second charging unit 600B may be grounded or discharged. At this time, the first charging unit 600A and the second charging unit 600B may be in a neutral state. According to embodiments, when a horizontal separation distance between the chemical liquid supply nozzle 462 and the first charging unit 600A exceeds a preset threshold, the first charging unit 600A may be grounded or discharged. According to embodiments, when a horizontal separation distance between the chemical liquid supply nozzle 462 and the second charging unit 600B exceeds a preset threshold, the second charging unit 600B may be grounded or discharged. For example, when the chemical liquid supply nozzle 462 is disposed at the center of the substrate W, the first charging unit 600A and the second charging unit 600B may be grounded or discharged.

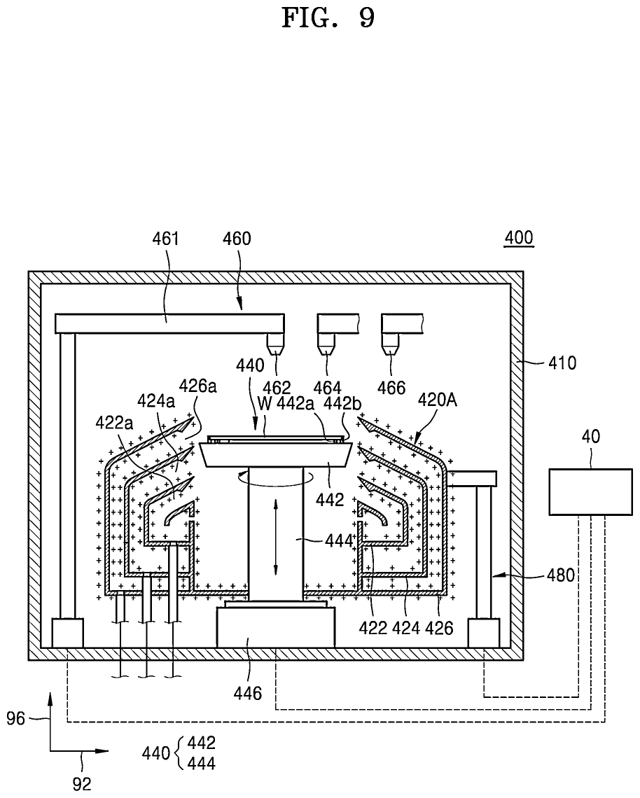

FIG. 9 is a schematic diagram of an embodiment of the substrate processing apparatus 400 of FIG. 1.

Referring to FIG. 9, the substrate processing apparatus 400 may include the housing 410, a collection cup 420A, the support unit 440, the liquid supply unit 460, the lifting unit 480, the controller 40, and the charging unit. The collection cup 420A of the substrate processing apparatus 400 may include a processing space with an open top. The collection cup 420A may include a plurality of collection bins 422a, 424a, and 426a. Each of the collection bins 422, 424, and 426 may include a collection space for collecting the liquid used to process the substrate W. Each of the plurality of collection bins 422a, 424a, and 426a may have a ring shape surrounding the support unit 440. Differences from FIG. 2 will be mainly explained below.

According to embodiments, the collection cup 420A may include a conductive member. The collection cup 420A may be charged with a positive or negative charge. In detail, when the chemical liquid supply nozzle 462 supplies a chemical liquid to the edge area of the substrate W, the collection cup 420A may be charged with a charge opposite to a charge of the chemical liquid. When the chemical liquid supply nozzle 462 supplies the chemical liquid to the center area of the substrate W, the collection cup 420A may be grounded or discharged. At this time, the collection cup 420A may be in a neutral state. According to embodiments, when a horizontal separation distance between the collection cup 420A and the chemical liquid supply nozzle 462 exceeds a preset threshold, the chemical liquid supply nozzle 462 may be grounded or discharged.

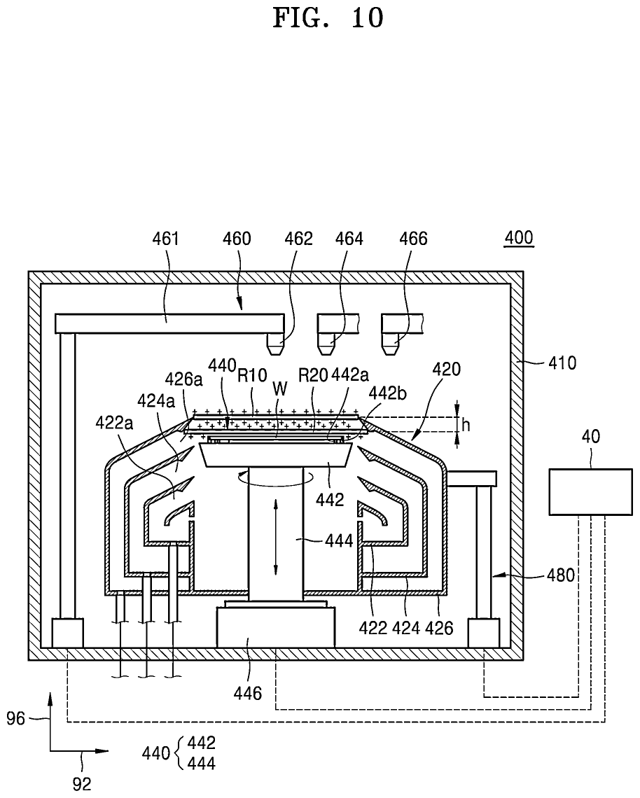

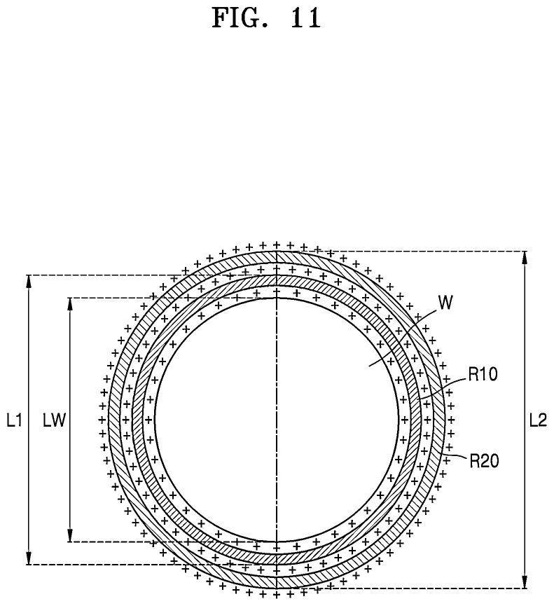

FIG. 10 is a schematic diagram of an embodiment of the substrate processing apparatus 400 of FIG. 2. FIG. 11 is a view for explaining a charging unit of FIG. 10. FIGS. 10 and 11 will be described in conjunction with reference to FIGS. 1 and 2, and the matters already described above with reference to FIGS. 1 and 2 will be briefly described or omitted.

Referring to FIGS. 10 and 11, the substrate processing apparatus 400 may include the charging unit disposed on the substrate W. The charging unit may include a plurality of ring members R10 and R20. A portion of the plurality of ring members R10 and R20 may be in contact with the collection cup 420 of the substrate processing apparatus 400. The plurality of ring members R10 and R20 may include a first ring member R10 and a second ring member R20. According to embodiments, the plurality of ring members R10 and R20 may be charged with positive or negative charges. The plurality of ring members R10 and R20 may be grounded or discharged. The first ring member R10 and the second ring member R20 may have thin ring shapes. The first ring member R10 and the second ring member R20 may have charges opposite to a charge of the chemical liquid supplied from the chemical liquid supply nozzle 462.

According to embodiments, the first ring member R10 and the second ring member R20 of the plurality of ring members R10 and R20 may be arranged apart from each other in the vertical direction. For example, the first ring member R10 may be disposed on the second ring member R20. According to embodiments, a diameter L1 of the first ring member R10 and a diameter L2 of the second ring member R20 may be greater than a diameter LW of the substrate W. The diameter L2 of the second ring member R20 may be greater than the diameter L1 of the first ring member R10.

The first ring member R10 and the second ring member R20 may be charged with the same charge. The first ring member R10 and the second ring member R20 may be charged with different charges. By charging the first ring member R10 and the second ring member R20 with different charges, an electrostatic attraction may be adjusted to be weak. By charging the first ring member R10 and the second ring member R20 with the same charge, an electrostatic attraction may be adjusted to be strong.

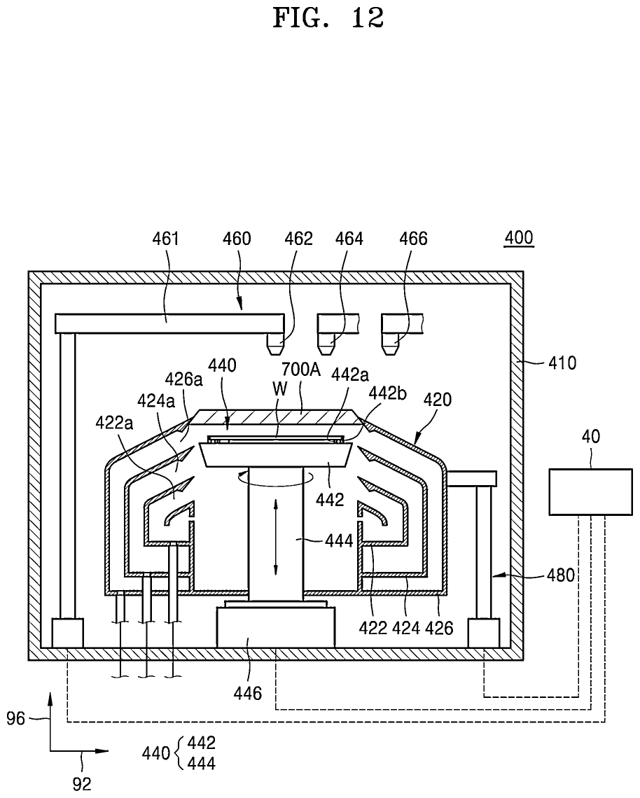

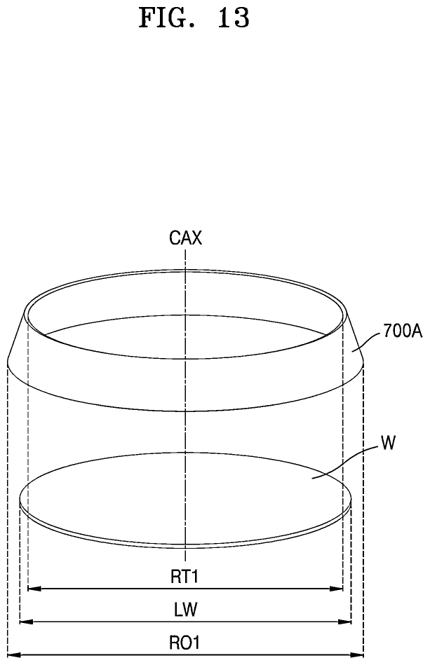

FIG. 12 is a schematic diagram of an embodiment of the substrate processing apparatus 400 of FIG. 2. FIG. 13 is a view for explaining a charging unit of FIG. 12. FIGS. 12 and 13 will be described in conjunction with reference to FIGS. 1 and 2, and the matters already described above with reference to FIGS. 1 and 2 will be briefly described or omitted.

Referring to FIGS. 12 and 13, the substrate processing apparatus 400 may include the charging unit disposed on the substrate W. The charging unit may include one ring member 700A. An outer circumferential surface of the one ring member 700A may be in contact with the collection cup 420 of the substrate processing apparatus 400. A diameter of the one ring member 700A may gradually decrease in a direction away from the substrate W. According to embodiments, the one ring member 700A may be charged with positive or negative charges. The one ring member 700A may be grounded or discharged. The one ring member 700A may have charges opposite to a charge of the chemical liquid supplied from the chemical liquid supply nozzle 462.

For example, a lower diameter RO1 of the one ring member 700A may be greater than an upper diameter RT1 of the one ring member 700A. The upper diameter RT1 of the one ring member 700A, which has the smallest value, may be less than the diameter LW of the substrate W. The lower diameter RO1 may be greater than the diameter LW of the substrate W. The one ring member 700A may have a hollow cylindrical shape in which a width gradually decreases in a direction away from the substrate W.

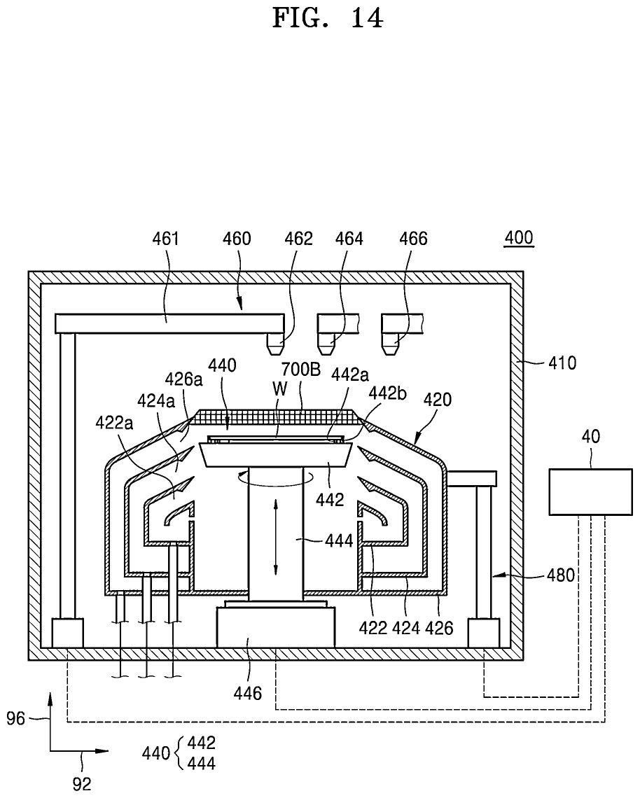

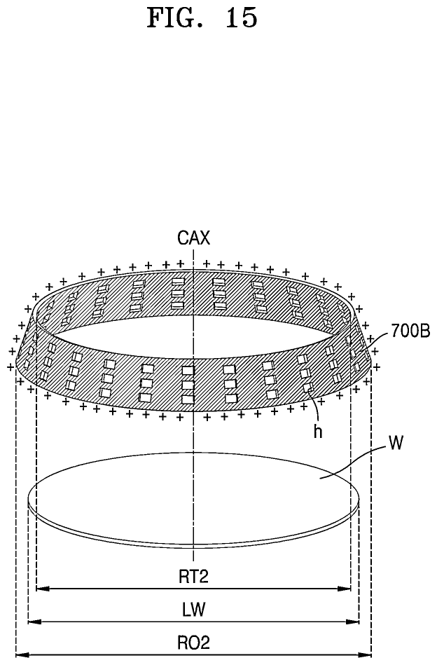

FIG. 14 is a schematic diagram of an embodiment of the substrate processing apparatus 400 of FIG. 2. FIG. 15 is a view for explaining a charging unit of FIG. 14. FIGS. 14 and 15 will be described in conjunction with reference to FIGS. 12 and 13, and the matters already described above with reference to FIGS. 12 and 13 will be briefly described or omitted. Differences from FIGS. 12 and 13 will now be mainly explained.

Referring to FIGS. 14 and 15, the substrate processing apparatus 400 may include the charging unit disposed on the substrate W. The charging unit may include one ring member 700B. An outer circumferential surface of the one ring member 700B may be in contact with the collection cup 420 of the substrate processing apparatus 400. A diameter of the one ring member 700B may gradually decrease in a direction away from the substrate W. According to embodiments, the one ring member 700B may be charged with positive or negative charges. The one ring member 700B may be grounded or discharged. The one ring member 700B may have charges opposite to a charge of the chemical liquid supplied from the chemical liquid supply nozzle 462.

For example, a lower diameter RO2 of the one ring member 700B may be greater than an upper diameter RT2 of the one ring member 700B. The upper diameter RT2 of the one ring member 700B, which has the smallest value, may be less than the diameter LW of the substrate W. The lower diameter RO2 may be greater than the diameter LW of the substrate W. The one ring member 700B may have a hollow cylindrical shape in which a width gradually decreases in a direction away from the substrate W. According to embodiments, the one ring member 700B may include a plurality of holes h on the outer circumferential surface of the one ring member 700B. The plurality of holes H may be arranged in a matrix form. The plurality of holes h are shown as including three holes in a vertical direction in the outer circumferential surface of the one ring member 700B, but embodiments are not limited thereto.

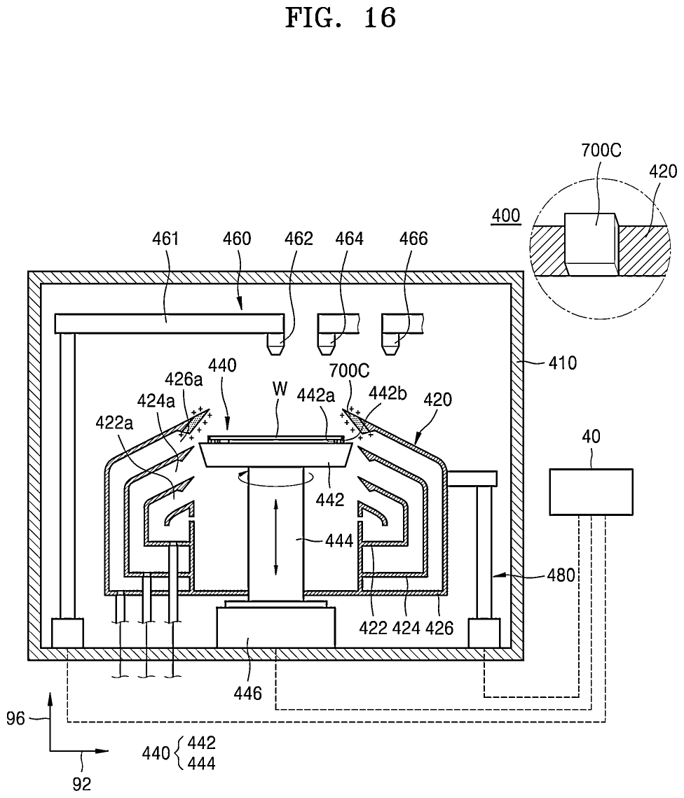

FIG. 16 is a schematic diagram of an embodiment of the substrate processing apparatus 400 of FIG. 2.

Referring to FIG. 16, the substrate processing apparatus 400 may include a charging unit 700C. One surface of the charging unit 700C may be in contact with the collection cup 420 of the substrate processing apparatus 400. According to embodiments, the charging unit 700C may be attached to both sides of the collection cup 420. The charging unit 700C may have a rectangular or regular hexagonal shape. However, embodiments are not limited thereto, and the charging unit 700C may have a circular or other shape.

According to embodiments, the charging unit 700C may be disposed on an edge of the substrate W, and a plurality of charging units 700C may be arranged along the inner circumferential surface of the collection cup 420. The charging unit 700C may be charged with negative or positive charge. The charging unit 700C may be grounded or discharged. The charging unit 700C may have charges opposite to the charge of the chemical liquid supplied from the chemical liquid supply nozzle 462.

The disclosure has been particularly shown and described with reference to exemplary embodiments thereof. The terminology used herein is for the purpose of describing exemplary embodiments only and is not intended to be limiting of the disclosure. Therefore, it will be understood by those skilled in the art that various changes in form and details may be made therein without departing from the spirit and scope of the disclosure as defined by the appended claims.

What is claimed is:

1. A substrate processing apparatus comprising:
a support unit configured to support a substrate and be rotatable;
a chemical liquid supply nozzle configured to supply a chemical liquid to a chemical liquid supply area of the substrate;
a collection cup configured to provide a space for collecting the chemical liquid; and
a charging unit disposed adjacent to the substrate,
wherein the charging unit is configured to capture droplets of the chemical liquid that collide with the substrate and scatter, and is charged with charges opposite to charges of the chemical liquid.

2. The substrate processing apparatus of claim 1, wherein
the charging unit is arranged to be spaced apart from the collection cup in a horizontal direction perpendicular to the support unit, and
when the chemical liquid has positive charges, the charging unit is charged with negative charges, and, when the chemical liquid has negative charges, the charging unit is charged with positive charges.

3. The substrate processing apparatus of claim 2, wherein the charging unit comprises:
a first body extending in a vertical direction perpendicular to the substrate;
a second body connected to the first body and extending in an inclined direction with respect to the first body; and
a protrusion protruding from the second body toward an upper surface of the substrate.

4. The substrate processing apparatus of claim 3, wherein
the first body is arranged to be spaced apart from the support unit, and
a length of the second body is less than a length of the first body.

5. The substrate processing apparatus of claim 2, wherein the charging unit is arranged not to vertically overlap the substrate.

6. The substrate processing apparatus of claim 1, wherein
the charging unit includes a first charging unit and a second charging unit arranged to be spaced apart from the first charging unit in a horizontal direction perpendicular to the support unit,
the first charging unit is arranged to be symmetrical with the second charging unit about the substrate,
the first charging unit comprises:
a first body extending in a vertical direction perpendicular to the substrate;
a second body connected to the first body and extending in an inclined direction with respect to the first body; and
a first protrusion protruding from the second body toward an upper surface of the substrate, and
the second charging unit comprises:
a third body extending in the vertical direction perpendicular to the substrate;
a fourth body connected to the third body and extending in an inclined direction with respect to the third body; and
a second protrusion protruding from the fourth body toward the upper surface of the substrate.

7. The substrate processing apparatus of claim 6, wherein at least one charging unit among the first charging unit and the second charging unit is charged with charges opposite to charges of the chemical liquid.

8. The substrate processing apparatus of claim 1, wherein the collection cup includes a conductive member and is charged with charges opposite to charges of the chemical liquid.

9. The substrate processing apparatus of claim 1, wherein the charging unit is in contact with the collection cup and includes a plurality of ring members arranged to be spaced apart from the substrate in a vertical direction perpendicular to the substrate.

10. The substrate processing apparatus of claim 9, wherein
the charging unit includes a first ring member and a second ring member, and
a center of each of the first ring member and the second ring member coincides with a center of the substrate.

11. The substrate processing apparatus of claim 10, wherein
a diameter of the first ring member is greater than a diameter of the substrate, and
a diameter of the second ring member is greater than the diameter of the first ring member.

12. The substrate processing apparatus of claim 8, wherein
the charging unit has a ring shape, and
a width of the charging unit decreases in a direction away from the substrate.

13. The substrate processing apparatus of claim 12, wherein
the charging unit includes a plurality of holes arranged in an outer circumferential surface of the charging unit, and
the plurality of holes are arranged in the outer circumferential surface in a matrix form.

14. A substrate processing apparatus comprising:
a housing configured to provide a processing space;
a support unit having a chuck for supporting a lower surface of a substrate in the processing space and a chuck pin formed to contact a lateral surface of the substrate, the support unit extending in a vertical direction perpendicular to a bottom surface of the housing;
a chemical liquid supply nozzle configured to supply a chemical liquid to a chemical liquid supply area of the substrate;
a charging unit disposed adjacent to the substrate;
a collection cup disposed within the housing and configured to collect the chemical liquid; and
a controller configured to control the chemical liquid supply nozzle, the charging unit, and the support unit,
wherein the charging unit is in contact with the collection cup, is disposed to be spaced apart from the substrate in the vertical direction, and has a ring shape.

15. The substrate processing apparatus of claim 11, wherein
the chemical liquid supply nozzle moves in a horizontal direction perpendicular to the vertical direction on the substrate, and
the charging unit is grounded when the chemical liquid supply nozzle is disposed on a central axis of the substrate.

16. The substrate processing apparatus of claim 11, wherein
the charging unit includes a first ring member and a second ring member spaced apart from each other,
a diameter of the first ring member and a diameter of the second ring member are greater than a diameter of the substrate, and
the diameter of the first ring member is less than the diameter of the second ring member.

17. The substrate processing apparatus of claim 11, wherein
a width of the charging unit decreases in a direction away from the substrate in the vertical direction,
the charging unit includes a plurality of holes, and
the plurality of holes are arranged in an outer circumferential surface of the charging unit in a matrix form.

18. A substrate processing apparatus comprising:
a housing configured to provide a processing space;
a support unit having a chuck for supporting a lower surface of a substrate in the processing space and a chuck pin formed to contact a lateral surface of the substrate, the support unit extending in a vertical direction perpendicular to a bottom surface of the housing;
a chemical liquid supply nozzle configured to supply a chemical liquid to a chemical liquid supply area of the substrate;
a charging unit disposed adjacent to the substrate;
a collection cup disposed within the housing and configured to collect the chemical liquid; and
a controller configured to control the chemical liquid supply nozzle, the charging unit, and the support unit,
wherein
the charging unit is disposed to be spaced apart from the substrate in the vertical direction, and has a ring shape, and
the charging unit is charged with charges opposite to the chemical liquid when the chemical liquid supply nozzle is disposed on a lateral surface of the substrate, and is grounded when the chemical liquid supply nozzle is disposed on a central axis of the substrate.

19. The substrate processing apparatus of claim 18, wherein the charging unit and the collection cup are charged with charges of same type.

20. The substrate processing apparatus of claim 18, wherein
the charging unit includes a first ring member and a second ring member,
a center of each of the first ring member and the second ring member is greater than a center of the substrate,
a diameter of the first ring member is greater than a diameter of the substrate, and
a diameter of the second ring member is greater than the diameter of the first ring member.
